(19) United States
(12) Patent Application Publication
(10) Pub. No.: US 2023/0377967 A1
(43) Pub. Date: Nov. 23, 2023

(54) METHOD OF FORMING THROUGH SILICON VIA AND TRENCH USING THE SAME MASK LAYER

(71) Applicant: MICRON TECHNOLOGY, INC., BOISE, ID (US)

(72) Inventors: Keizo Kawakita, Higashihiroshima (JP); Hidenori Yamaguchi, Higashihiroshima (JP)

(73) Assignee: MICRON TECHNOLOGY, INC., BOISE, ID (US)

(21) Appl. No.: 17/751,297

(22) Filed: May 23, 2022

(51) Int. Cl. H01L 21/768; H01L 23/48

(52) U.S. Cl. CPC H01L 21/76898; H01L 23/481; H01L 21/76816; H01L 21/31144

(57) ABSTRACT

Disclosed herein is a method that includes: forming a mask layer on a semiconductor substrate; forming a photoresist on the mask layer; performing non-uniform exposure on the photoresist to provide a first patterned photoresist which includes a first region where the photoresist is removed to expose the mask layer and a second region where a part of the photoresist remains; first etching using the first patterned photoresist to remove the mask layer in the first region and form a first trench in the first region of the semiconductor substrate; second etching to provide a second patterned photoresist which includes the second region where the photoresist is removed; third etching using the second patterned photoresist to remove the mask layer in the second region; and fourth etching to deepen the first trench in the first region and form a second trench shallower than the first trench in the second region.

### BACKGROUND

A semiconductor device such as a DRAM may be provided with a TSV penetrating a silicon substrate. In order to form a TSV, a hard mask is patterned with a photoresist used as a mask. Etching is then performed through the patterned hard mask to form a through hole in a silicon substrate. Thereafter, a metal such as Cu is embedded in the through hole. In this manner, semiconductor devices provided with a TSV require a dedicated process for forming the TSV.

### BRIEF DESCRIPTION OF THE DRAWINGS

FIG. 1 is a schematic cross-sectional view of a semiconductor device according to a first embodiment of the present disclosure;

FIGS. 2A to 2J are process diagrams for explaining a manufacturing method of the semiconductor device shown in FIG. 1;

FIG. 3 is a schematic cross-sectional view of a semiconductor device according to a second embodiment of the present disclosure;

FIGS. 4A to 4I are process diagrams for explaining a manufacturing method of the semiconductor device shown in FIG. 3;

FIG. 4J is a schematic cross-sectional view of a semiconductor device according to a modification of the second embodiment;

FIG. 5 is a schematic cross-sectional view of a semiconductor device according to a third embodiment of the present disclosure; and

FIGS. 6A to 6I are process diagrams for explaining a manufacturing method of the semiconductor device shown in FIG. 5.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

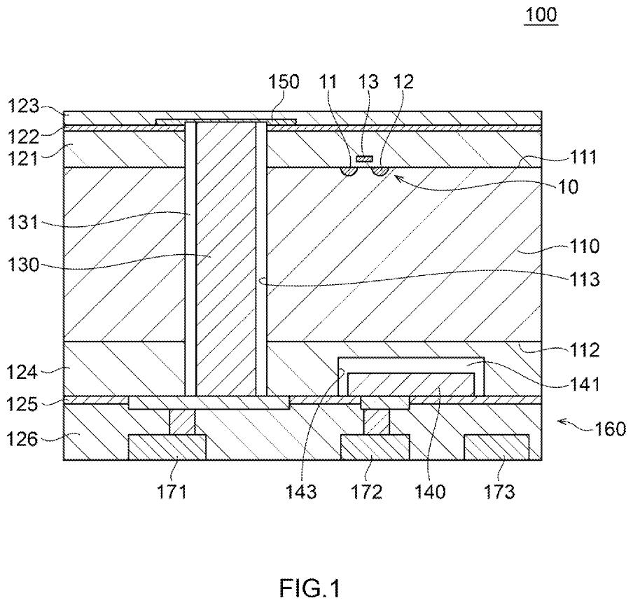

FIG. 1 is a schematic cross-sectional view of a semiconductor device 100 according to a first embodiment of the present disclosure. The semiconductor device 100 shown in FIG. 1 includes a semiconductor substrate 110 made of, for example, silicon, insulating layers 121 to 123 stacked on a main surface 111 of the semiconductor substrate 110, insulating layers 124 to 126 stacked on a back 112 of the semiconductor substrate 110, and a TSV 130 penetrating the semiconductor substrate 110. The main surface 111 of the semiconductor substrate 110 has an active element such as a transistor 10 formed thereon. The transistor 10 includes a source region 11 and a drain region 12 provided in the semiconductor substrate 110 and a gate electrode 13 covering the semiconductor substrate 110. The insulating layers 121 to 126 are made of, for example, silicon oxide or silicon nitride.

The TSV 130 is provided to penetrate the semiconductor substrate 110 and the insulating layers 121 and 124. The TSV 130 is made of Cu, for example. One end of the TSV 130 is coupled to a conductor pattern 150 provided on the insulating layer 122. The conductor pattern 150 is coupled to the transistor 10 via a wiring pattern (not shown). The other end of the TSV 130 is coupled to a back electrode 171 via a redistribution layer 160. An insulating layer 131, which is made of silicon oxide, for example, is provided between the TSV 130 and the semiconductor substrate 110 to insulate the TSV 130 and the semiconductor substrate 110 from each other. A redistribution pattern 140 is embedded in the insulating layer 124. The redistribution pattern 140 forms a part of the redistribution layer 160. The redistribution pattern 140 may be coupled to another TSV (not shown). The redistribution pattern 140 is coupled to a back electrode 172. A back electrode 173 coupled to still another TSV is also provided on the back of the semiconductor device 100.

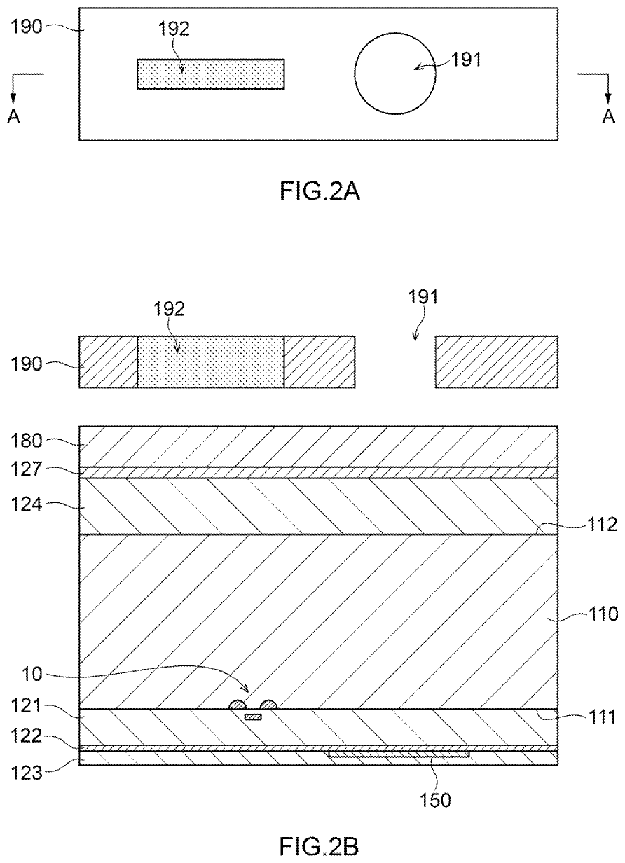

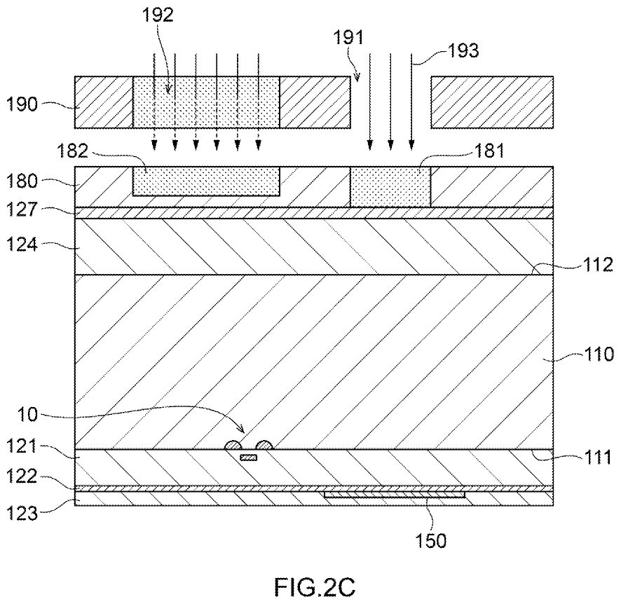

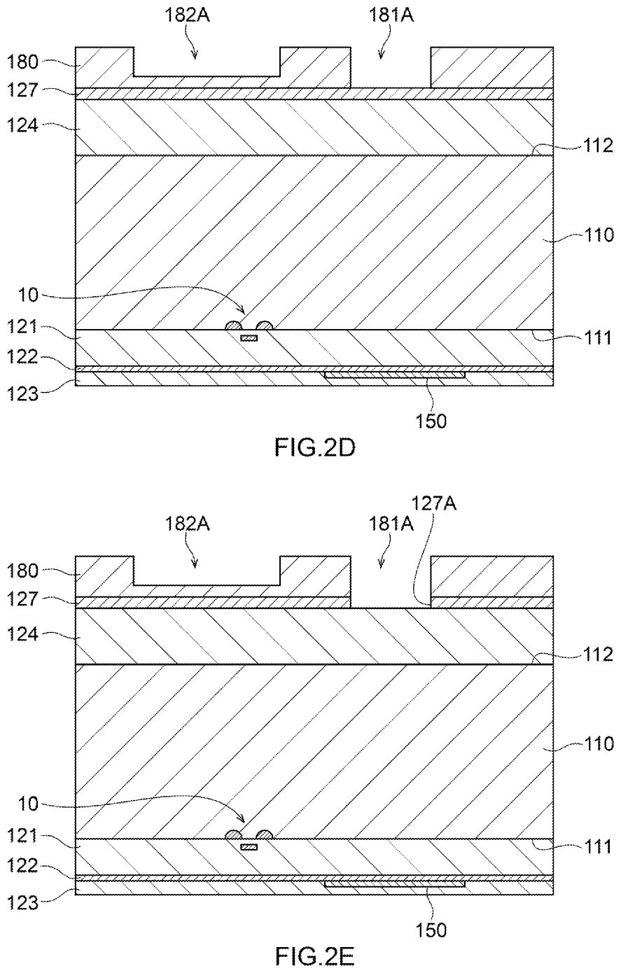

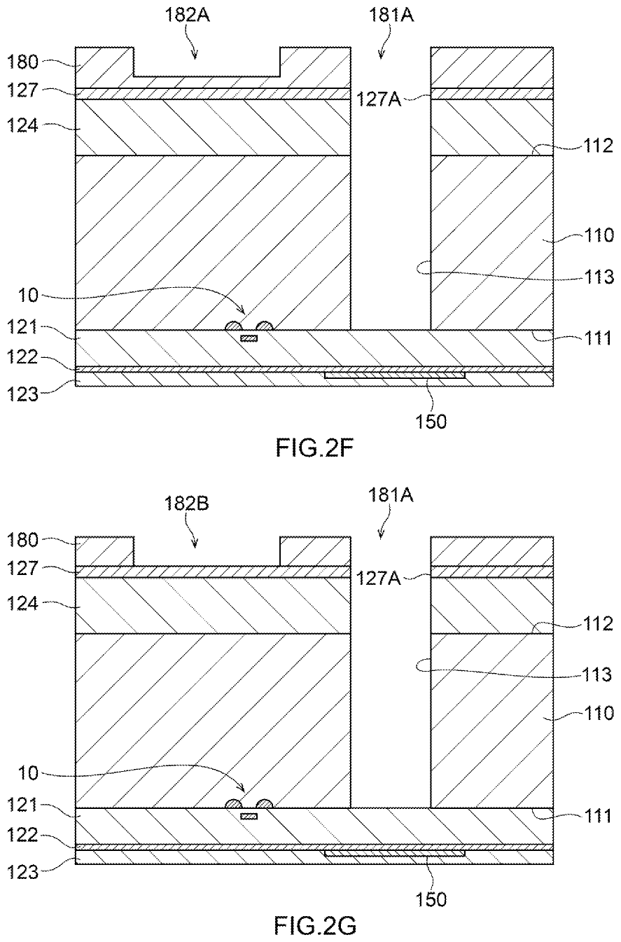

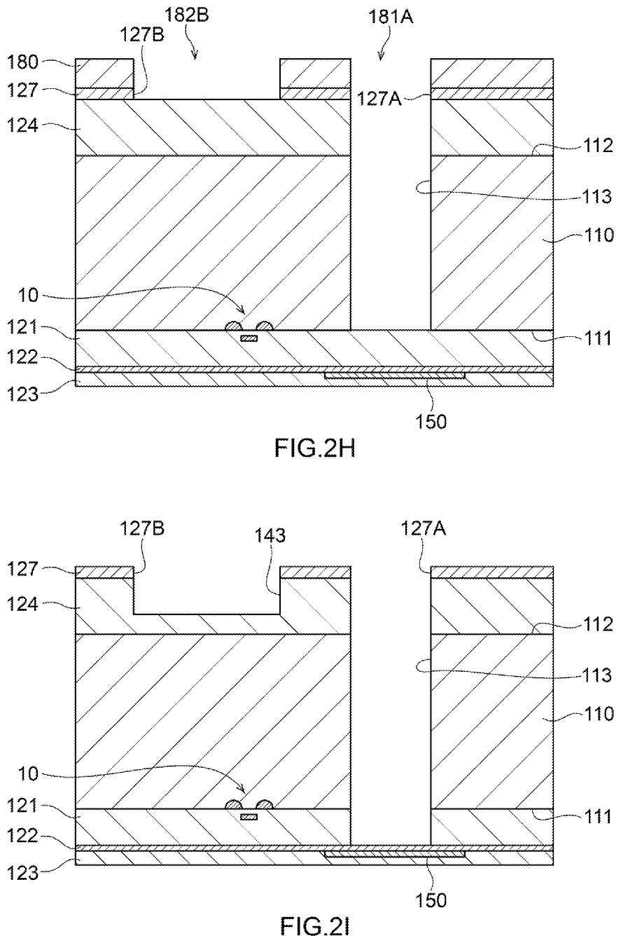

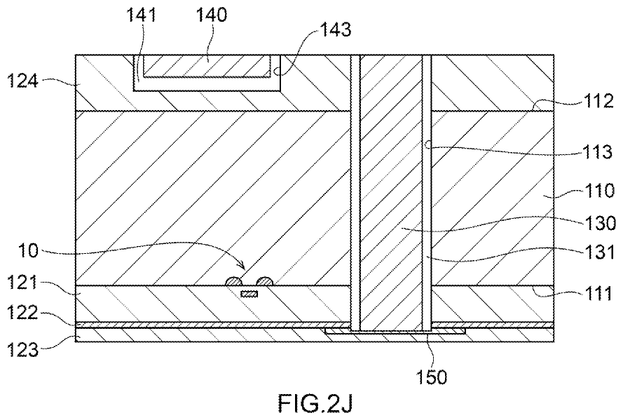

Next, a manufacturing method of the semiconductor device 100 is described. FIG. 2A is a schematic top view, and FIG. 2B is a schematic cross-sectional view taken along a line A-A in FIG. 2A. First, as shown in FIGS. 2A and 2B, the semiconductor substrate 110 with the transistor 10 formed on the main surface 111 is prepared, the insulating layer 124 and a hard mask 127 are stacked on the back 112 of the semiconductor substrate 110, and thereafter a photoresist 180 is formed on the surface of the hard mask 127. The insulating layer 124 may be a multilayer film including alternating layers made of a plurality of insulating materials. The hard mask 127 is made of a material that ensures a sufficient etching rate for at least the insulating material forming the outermost surface of the insulating layer 124. Examples of such a material include silicon oxide, silicon nitride, carbon, and metals. Subsequently, a photomask 190 is positioned over the photoresist 180. The photomask 190 has apertures 191 and 192 that pass a light therethrough. The light transmissibility of the aperture 191 is approximately 100%, whereas the light transmissibility of the aperture 192 is lower than that of the aperture 191 and is, for example, 50%. This low light-transmissibility aperture 192 is obtained by regularly arranging a plurality of light-shielding patterns each having a size sufficiently smaller than the wavelength of the light used for exposure. In the example shown in FIG. 2A, the planar shape of the aperture 191 is circular, and the planar shape of the aperture 192 is rectangular.

Next, as shown in FIG. 2C, irradiation with a light 193 is performed via the photomask 190, whereby the photoresist 180 is exposed to the light. A region 181 under the aperture 191 is thereby exposed to the light substantially completely. Meanwhile, a region 182 under the aperture 192 is incompletely exposed to the light because the energy of irradiation is low. That is, only an upper region of the region 182 is exposed to the light, but a lower portion thereof is not exposed. Thereafter, as shown in FIG. 2D, the exposed regions are removed by development of the photoresist 180. Consequently, an opening 181A that allows the hard mask 127 to be exposed is formed in the region 181 under the aperture 191, and a recess 182A is formed in the region 182 under the aperture 192. The recess 182A is a portion where the photoresist 180 becomes thin locally. The hard mask 127 is not exposed in the recess 182A. Next, by using the photoresist 180 as a mask, the hard mask 127 is etched to form an opening 127A as shown in FIG. 2E, and the insulating layer 124 and the semiconductor substrate 110 are then etched as shown in FIG. 2F. With this process, a through hole 113 is formed at a position under the opening 181A of the photoresist 180. Since the bottom of the through hole 113 is closed with the insulating layer 121, the through hole 113 has a trench shape.

Next, as shown in FIG. 2G the photoresist 180 is etched back to reduce its thickness. Thereby, the recess 182A is changed to an opening 182B, so that the surface of the hard mask 127 having been covered by the recess 182A is exposed. The hard mask 127 is etched in this state with the photoresist 180 used as a mask, whereby an opening 127B is formed in the hard mask 127 at a position under the opening 182B of the photoresist 180 as shown in FIG. 2H. With this process, the two openings 127A and 127B are formed in the hard mask 127. Next, the photoresist 180 is removed, and thereafter etching is performed under a condition in which etching rates to the insulating layers 121 and 124 are higher than an etching rate to the hard mask 127. By this etching, as shown in FIG. 2I, the insulating layer 121 is etched at a position under the opening 127A of the hard mask 127, and the insulating layer 124 is etched at a position under the opening 127B of the hard mask 127. That is, the trench under the opening 127A of the hard mask becomes deeper, and a new trench 143 is formed at the position under the opening 127B of the hard mask 127. Subsequently, as shown in FIG. 2J, insulating layers 131 and 141 are formed on the inner wall of the through hole 113 and the inner wall of the trench 143, respectively, and the TSV 130 and the redistribution pattern 140 each formed by a conductive member are embedded in the through hole 113 and the trench 143, respectively. The TSV 130 and the redistribution pattern 140 may be formed simultaneously. The redistribution layer 160 and the back electrodes 171 to 173 are then formed, thereby completing the semiconductor device 100 shown in FIG. 1.

The through hole 113 in which the TSV 130 is to be embedded and the trench 143 in which the redistribution pattern 140 is to be embedded are formed using the same mask in the process described above. Therefore, the number of manufacturing processes can be reduced, and no misalignment occurs in the positional relation between the TSV 130 and the redistribution pattern 140.

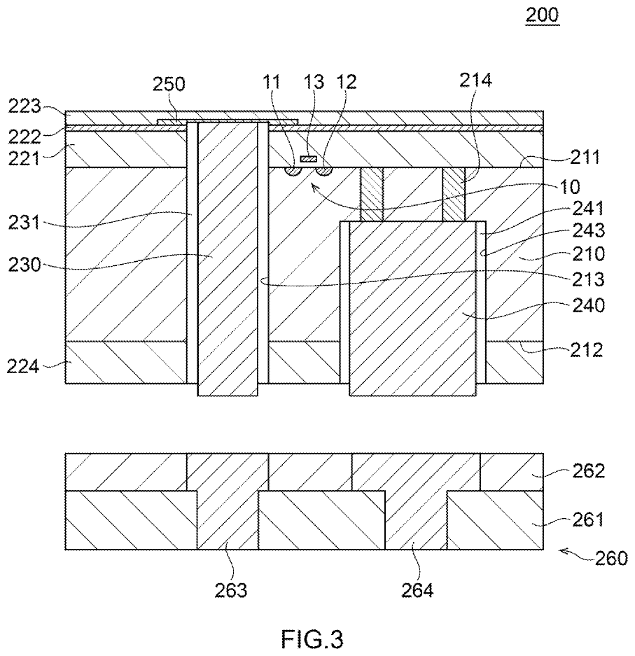

FIG. 3 is a schematic cross-sectional view of a semiconductor device 200 according to a second embodiment of the present disclosure. The semiconductor device 200 shown in FIG. 3 includes a semiconductor substrate 210 made of, for example, silicon, insulating layers 221 to 223 stacked on a main surface 211 of the semiconductor substrate 210, an insulating layer 224 formed on a back 212 of the semiconductor substrate 210, a TSV 230 penetrating the semiconductor substrate 210, and a power line 240 embedded in the semiconductor substrate 210. The main surface 211 of the semiconductor substrate 210 has an active element such as the transistor 10 formed thereon. The insulating layers 221 to 224 are made of silicon oxide or silicon nitride, for example.

The TSV 230 is provided to penetrate the semiconductor substrate 210 and the insulating layers 221 and 224. One end of the TSV 230 is coupled to a conductor pattern 250 provided on the insulating layer 222. The other end of the TSV 230 projects from a surface of the insulating layer 224. An insulating layer 231, which is made of silicon oxide, for example, is provided between the TSV 230 and the semiconductor substrate 210 to surely insulate the TSV 230 and the semiconductor substrate 210 from each other. The power line 240, which is made of the same conductive material as the TSV 230, is embedded in a trench 243 provided in the insulating layer 224 and the semiconductor substrate 210. One end of the power line 240 is in contact with a conductor plug 214 embedded in the semiconductor substrate 210. The conductor plug 214 is coupled to the source region 11 of the transistor 10 via a power line (not shown) provided on the main surface 211 of the semiconductor substrate 210. The other end of the power line 240 projects from the surface of the insulating layer 224.

As shown in FIG. 3, a redistribution substrate 260 is joined to the back of the semiconductor device 200. The redistribution substrate 260 includes a semiconductor substrate 261 made of, for example, silicon and an insulating layer 262 provided on a surface of the semiconductor substrate 261. Terminal electrodes 263 and 264 are embedded in the semiconductor substrate 261 and the insulating layer 262. The semiconductor device 200 and the redistribution substrate 260 are joined to each other to bring the terminal electrodes 263 and 264 and the TSV 230 and the power line 240 into contact with each other, respectively.

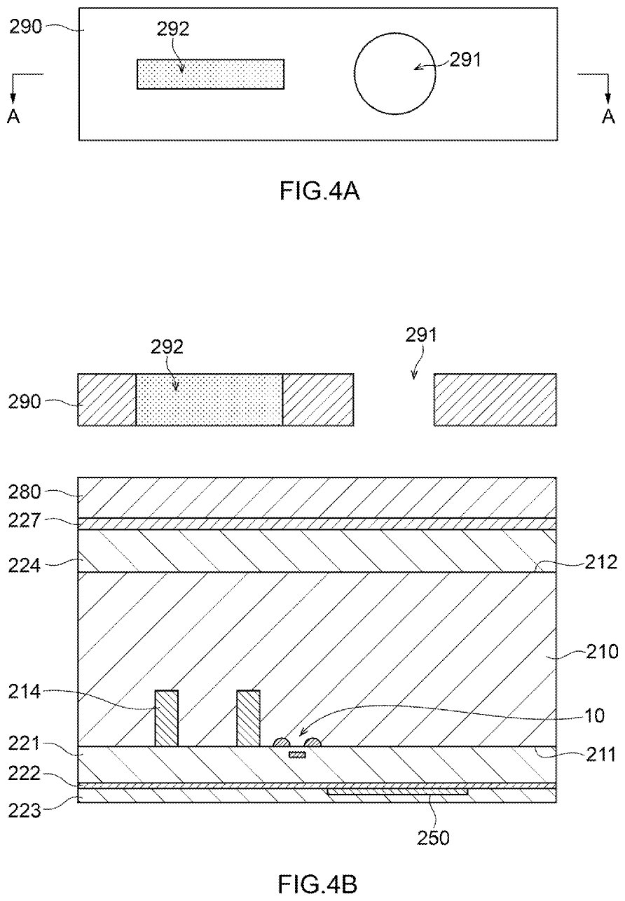

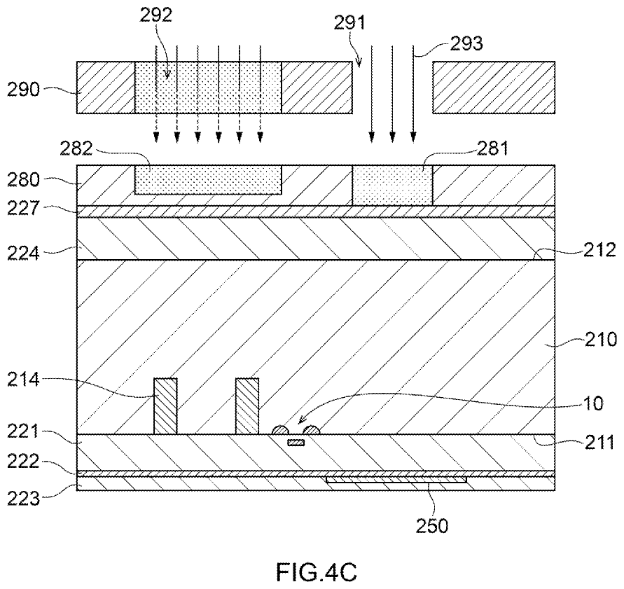

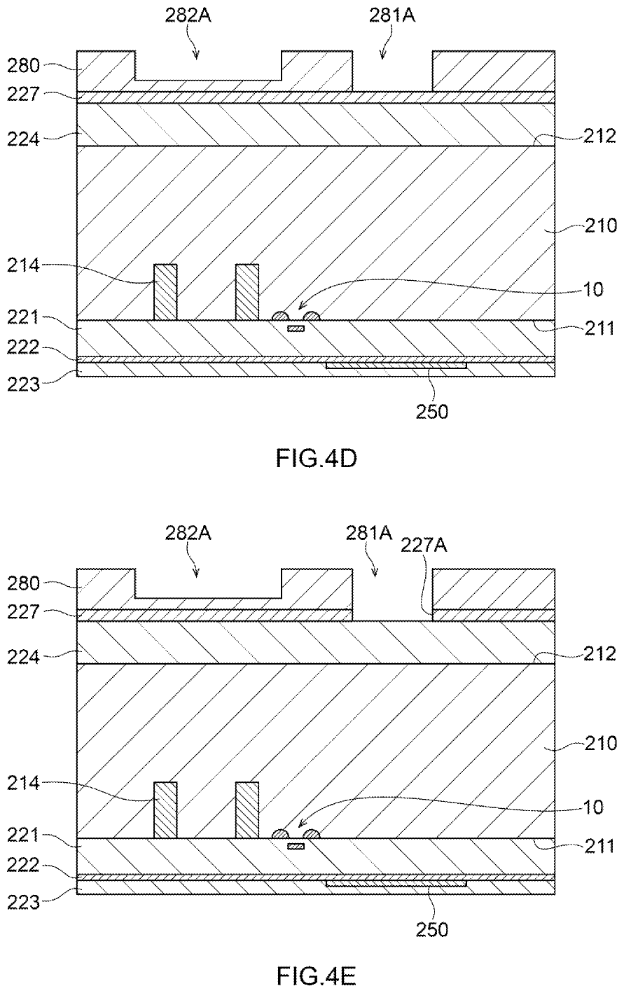

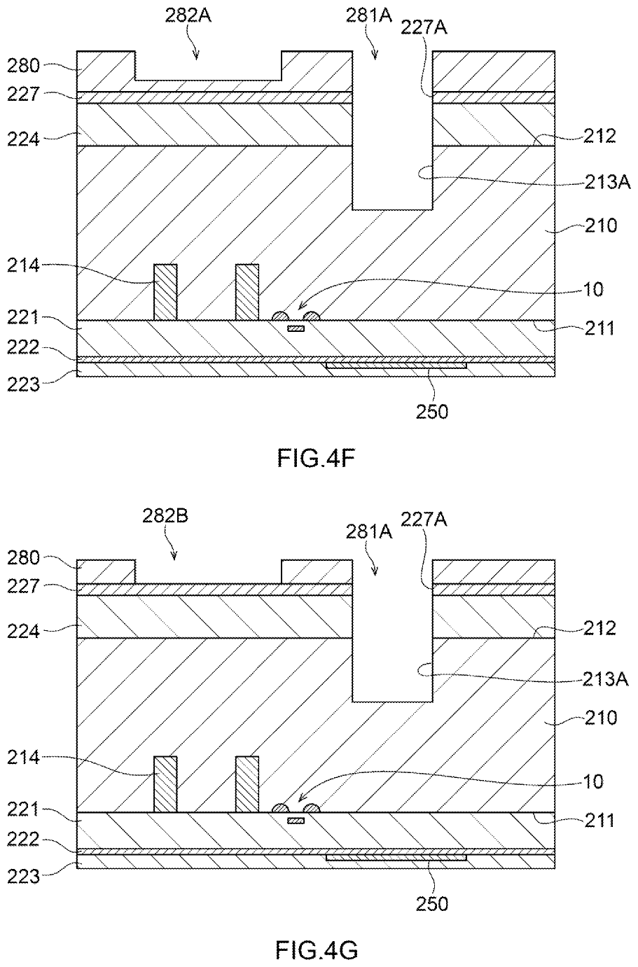

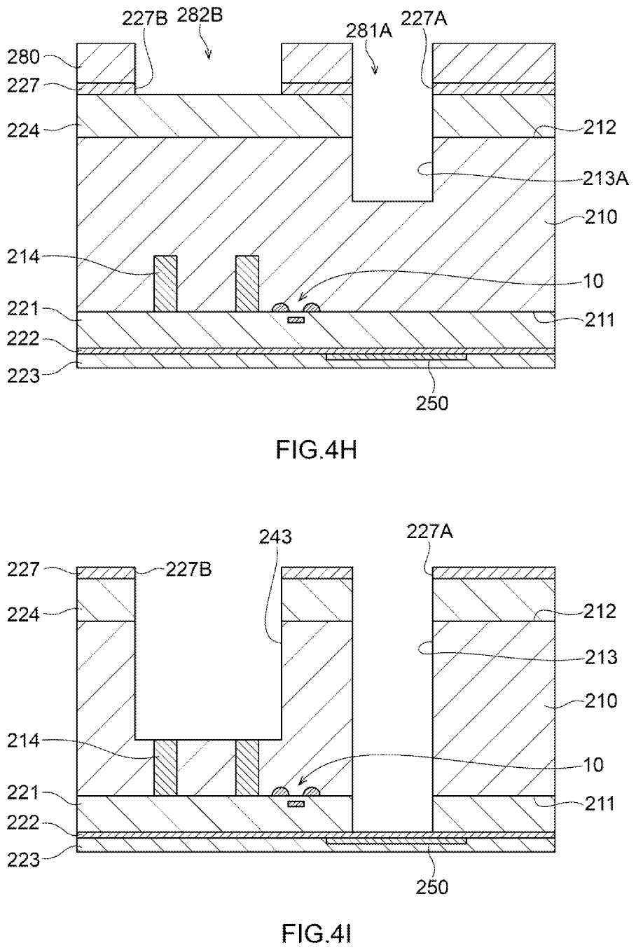

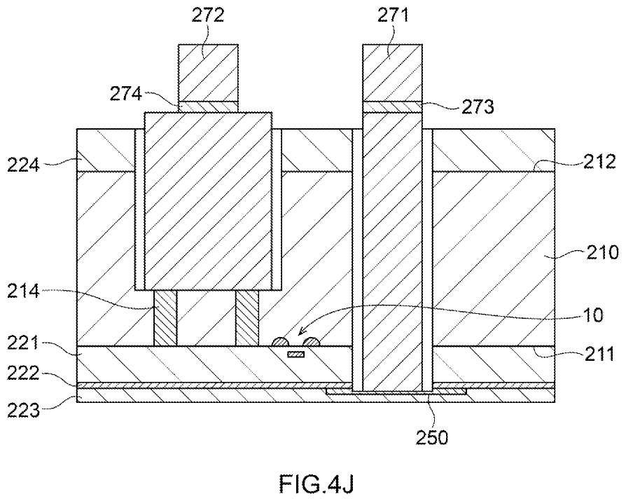

Next, a manufacturing method of the semiconductor device 200 is described. FIG. 4A is a schematic top view, and FIG. 4B is a schematic cross-sectional view taken along a line A-A in FIG. 4A. First, as shown in FIGS. 4A and 4B, the semiconductor substrate 210 with the transistor 10 formed on the main surface 211 is prepared, the insulating layer 224 and a hard mask 227 are stacked on the back 212 of the semiconductor substrate 210, and thereafter a photoresist 280 is formed on a surface of the hard mask 227. Subsequently, a photomask 290 is laid onto the photoresist 280. The photomask 290 has apertures 291 and 292 that pass a light therethrough. The light transmissibility of the aperture 291 is approximately 100%, whereas the light transmissibility of the aperture 292 is lower than that of the aperture 291 and is, for example, 50%.

Next, as shown in FIG. 4C, irradiation with a light 293 is performed via the photomask 290, whereby the photoresist 280 is exposed to the light. Thereby, a region 281 under the aperture 291 is exposed to the light substantially completely. Meanwhile, a region 282 under the aperture 292 is incompletely exposed to the light because the energy of irradiation is low. That is, only an upper region of the region 282 is exposed to the light, and a lower portion thereof is not exposed. Thereafter, the exposed regions are removed by development of the photoresist 280 as shown in FIG. 4D. Consequently, an opening 281A that allows the hard mask 227 to be exposed is formed in the region 281 under the aperture 291, and a recess 282A is formed in the region 282 under the aperture 292. The recess 282A is a portion where the photoresist 280 becomes thin locally. The hard mask 227 is not exposed in the recess 282A. Next, by using the photoresist 280 as a mask, the hard mask 227 is etched to form an opening 227A as shown in FIG. 4E, and the insulating layer 224 and the semiconductor substrate 210 are then etched to form a trench 213A as shown in FIG. 4F. The trench 213A does not penetrate the semiconductor substrate 210.

Next, as shown in FIG. 4G the photoresist 280 is etched back to reduce its thickness, so that the recess 282A is changed to an opening 282B and the surface of the hard mask 227 having been covered by the recess 282A is exposed. The hard mask 227 is etched in this state with the photoresist 280 used as a mask, whereby an opening 227B is formed in the hard mask 227 at a position under the opening 282B of the photoresist 280, as shown in FIG. 4H. With this process, the two openings 227A and 227B are formed in the hard mask 227. Next, the photoresist 280 is removed, and thereafter etching is performed under a condition in which etching rates to the insulating layers 221 and 224 and the semiconductor substrate 210 are higher than an etching rate to the hard mask 227. By this etching, as shown in FIG. 4I, the trench 213A penetrates the semiconductor substrate 210 and the insulating layer 221 to form the through hole 213, and a trench 243 is formed at a position under the opening 227B of the hard mask 227. That is, the trench 213A under the opening 227A of the hard mask 227 becomes deeper, and the new trench 243 is formed at the position under the opening 227B of the hard mask 227. The conductor plug 214 is exposed on the bottom of the trench 243. Insulating layers 231 and 241 are then formed on the inner wall of the through hole 213 and the inner wall of the trench 243, respectively, and thereafter the TSV 230 and the power line 240 are embedded in the through hole 213 and the trench 243, respectively. The semiconductor device 200 shown in FIG. 3 is thereby completed.

According to the semiconductor device 200 of the present embodiment, a power voltage can be supplied from the back 212 side of the semiconductor substrate 210 through the power line 240 and the conductor plug 214. Further, it is not required to join the redistribution substrate 260 to the back of the semiconductor device 200. Instead, as shown in FIG. 4J, pillar electrodes 271 and 272 may be formed at ends of the TSV 230 and the power line 240 via feeding films 273 and 274 for plating.

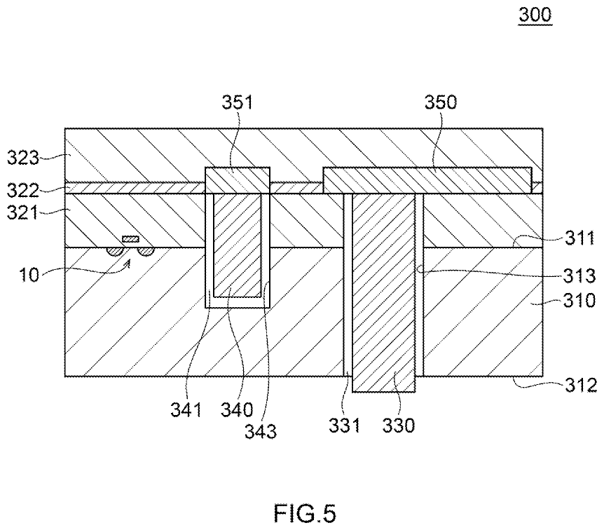

FIG. 5 is a schematic cross-sectional view of a semiconductor device 300 according to a third embodiment of the present disclosure. The semiconductor device 300 shown in FIG. 5 includes a semiconductor substrate 310 made of, for example, silicon, insulating layers 321 to 323 stacked on a main surface 311 of the semiconductor substrate 310, a TSV 330 penetrating the semiconductor substrate 310, and a capacitor electrode 340 embedded in the semiconductor substrate 310. The main surface 311 of the semiconductor substrate 310 has an active element such as the transistor 10 formed thereon. The insulating layers 321 to 323 are made of silicon oxide or silicon nitride, for example.

The TSV 330 is provided to penetrate the semiconductor substrate 310 and the insulating layer 321. One end of the TSV 330 is coupled to a conductor pattern 350 provided on the insulating layer 321. The other end of the TSV 330 projects from the back 312 of the semiconductor substrate 310. An insulating layer 331, which is made of silicon oxide, for example, is provided between the TSV 330 and the semiconductor substrate 310 to surely insulate the TSV 330 and the semiconductor substrate 310 from each other. The capacitor electrode 340, which is made of the same material as the TSV 330, is embedded in a trench 343 provided in the semiconductor substrate 310. The capacitor electrode 340 is coupled to a power line 351. The capacitor electrode 340 and the semiconductor substrate 310 face each other with an insulating layer 341 made of, for example, silicon oxide arranged therebetween to form a MOS capacitor. The MOS capacitor including the capacitor electrode 340 can be used as a compensation capacitance for stabilizing a power voltage.

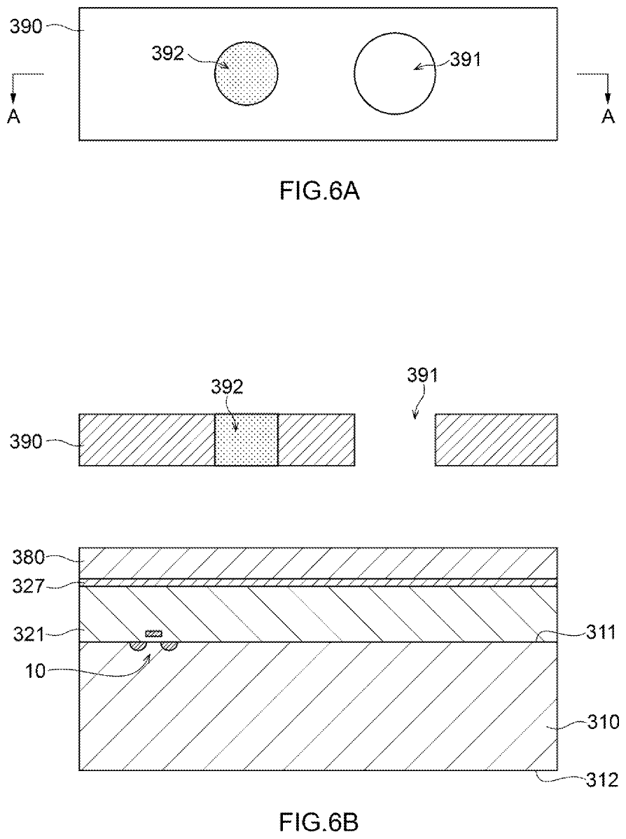

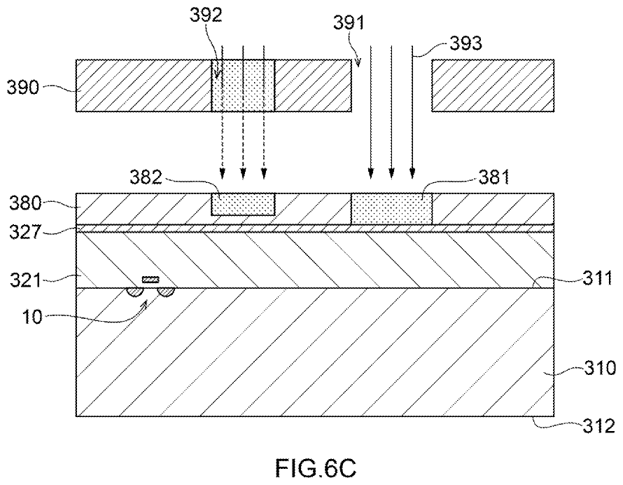

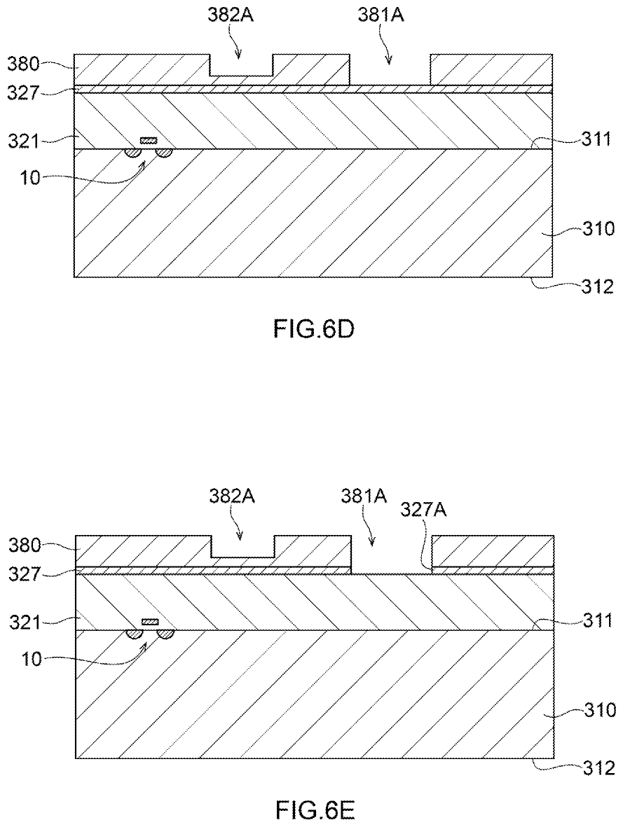

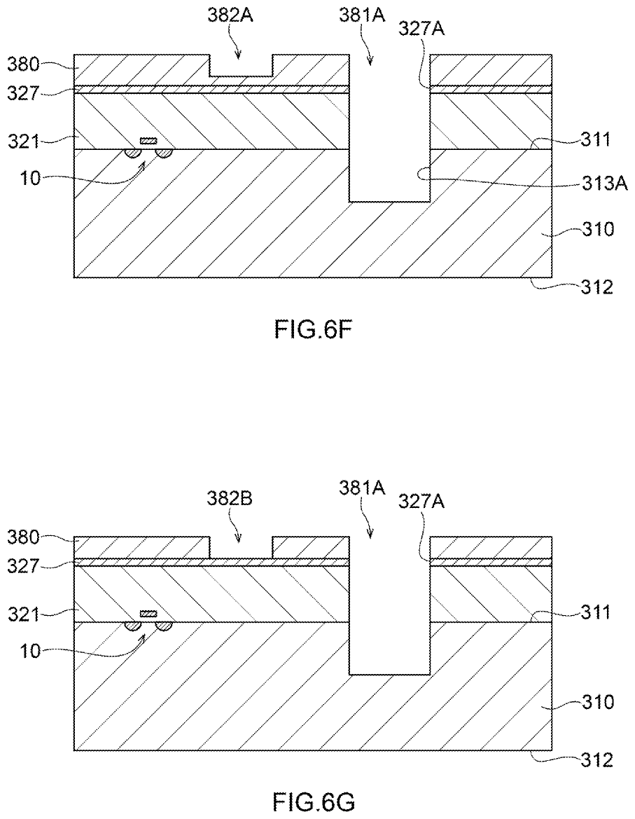

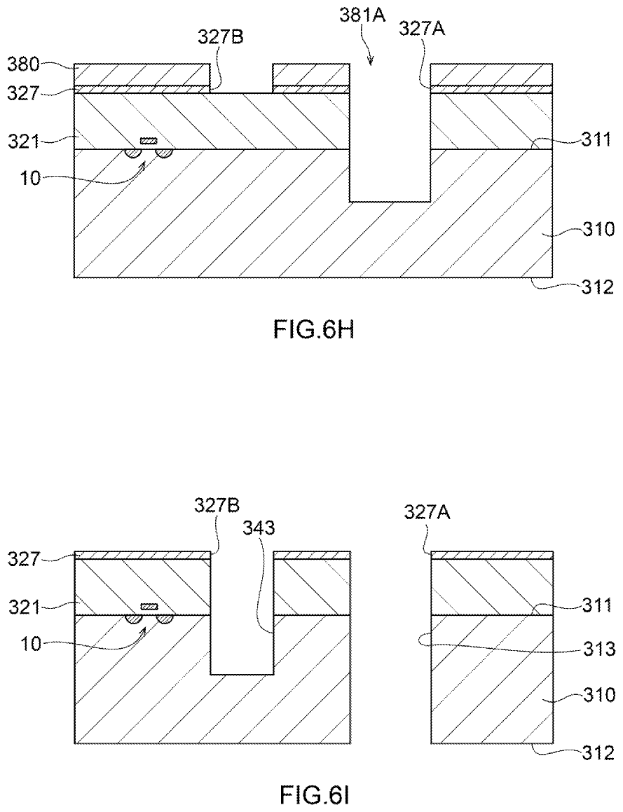

Next, a manufacturing method of the semiconductor device 300 is described. FIG. 6A is a schematic top view, and FIG. 6B is a schematic cross-sectional view taken along a line A-A in FIG. 6A. First, as shown in FIGS. 6A and 6B, the semiconductor substrate 310 with the transistor 10 formed on the main surface 311 is prepared, the insulating layer 321 and a hard mask 327 are stacked on the main surface 311 of the semiconductor substrate 310, and thereafter a photoresist 380 is formed on a surface of the hard mask 327. Subsequently, a photomask 390 is laid onto the photoresist 380. The photomask 390 has apertures 391 and 392 that pass a light therethrough. The light transmissibility of the aperture 391 is approximately 100%, whereas the light transmissibility of the aperture 392 is lower than that of the aperture 391 and is, for example, 50%. In the example shown in FIG. 6A, the planar shapes of the apertures 391 and 392 are both circular.

Next, as shown in FIG. 6C, irradiation with a light 393 is performed via the photomask 390, whereby the photoresist 380 is exposed to the light. A region 381 under the aperture 391 is thereby exposed to the light substantially completely. Meanwhile, a region 382 under the aperture 392 is incompletely exposed to the light because the energy of irradiation is low. That is, only an upper region of the region 382 is exposed to the light, and a lower portion thereof is not exposed. Thereafter, as shown in FIG. 6D, the exposed regions are removed by development of the photoresist 380. Consequently, an opening 381A that allows the hard mask 327 to be exposed is formed in the region 381 under the aperture 391, and a recess 382A is formed in the region 382 under the aperture 392. The recess 382A is a portion where the photoresist 380 becomes thin locally. The hard mask 327 is not exposed in the recess 382A. Next, by using the photoresist 380 as a mask, the hard mask 327 is etched to form an opening 327A thereon as shown in FIG. 6E, and the insulating layer 321 and the semiconductor substrate 310 are then etched to form a trench 313A as shown in FIG. 6F. The trench 313A does not penetrate the semiconductor substrate 310.

Next, as shown in FIG. 6G the photoresist 380 is etched back to reduce its thickness, so that the recess 382A is changed to an opening 382B and the surface of the hard mask 327 having been covered by the recess 382A is exposed. The hard mask 327 is etched in this state with the photoresist 380 used as a mask, whereby an opening 327B is formed in the hard mask 327 at a position under the opening 382B of the photoresist 380 as shown in FIG. 6H. With this process, the two openings 327A and 327B are formed in the hard mask 327. Next, the photoresist 380 is removed, and thereafter etching is performed under a condition in which etching rates to the insulating layer 321 and the semiconductor substrate 310 are higher than an etching rate to the hard mask 327. By this etching, as shown in FIG. 6I, the trench 313A penetrates the semiconductor substrate 310 to form the through hole 313, and the trench 343 is formed at a position under the opening 327B of the hard mask 327. That is, the trench 313A located the opening 327A of the hard mask 327 becomes deeper, and the new trench 343 is formed at the position under the opening 327B of the hard mask 327. Subsequently, insulating layers 331 and 341 are formed on the inner wall of the through hole 313 and the inner wall of the trench 343, respectively, and thereafter the TSV 330 and the capacitor electrode 340 are embedded in the through hole 313 and the trench 343, respectively. The semiconductor device 300 shown in FIG. 5 is thereby completed.

As described above, the through hole 313 and the trench 343 may be formed from the main surface 311 side of the semiconductor substrate 310.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. A method comprising:
forming a mask layer on an apparatus including a semiconductor substrate;
forming a photoresist on the mask layer;
performing non-uniform exposure on the photoresist to provide a first patterned photoresist which includes a first region where the photoresist is removed to expose the mask layer and a second region where a part of the photoresist remains;
first etching using the first patterned photoresist to remove the mask layer in the first region and form a first trench in the first region of the semiconductor substrate;
second etching to provide a second patterned photoresist which includes the second region where the photoresist is removed;
third etching using the second patterned photoresist to remove the mask layer in the second region; and
fourth etching to deepen the first trench in the first region and form a second trench shallower than the first trench in the second region.

2. The method of claim 1, further comprising forming first and second conductive material in the first and second trenches, respectively, after the fourth etching.

3. The method of claim 2, wherein the apparatus further includes a first insulating layer arranged between a first surface of the semiconductor substrate and the mask layer.

4. The method of claim 3,
wherein the apparatus further includes a second insulating layer formed on a second surface of the semiconductor substrate such that the semiconductor substrate is sandwiched between the first and second insulating layers, and
wherein the first trench penetrates the first insulating layer, the semiconductor substrate, and the second insulating layer by the fourth etching.

5. The method of claim 4,
wherein the semiconductor substrate having a transistor formed on the second surface of the semiconductor substrate, and
wherein the transistor is coupled to the first conductive material.

6. The method of claim 5, wherein the first etching is performed by using the second insulating layer as an etching stopper.

7. The method of claim 6, wherein the second trench is formed in the first insulating layer without reaching the semiconductor substrate by the fourth etching.

8. The method of claim 5, wherein the first trench is formed in the first insulating layer and the semiconductor substrate without penetrating the semiconductor substrate by the first etching.

9. The method of claim 8, wherein the second trench is formed in the first insulating layer and the semiconductor substrate without penetrating the semiconductor substrate by the fourth etching.

10. The method of claim 9,
wherein the semiconductor substrate includes a conductor plug embedded therein,
wherein the conductor plug is exposed on a bottom of the second trench by the fourth etching, and
wherein the second conductive material is in contact with the conductor plug.

11. The method of claim 3,
wherein the semiconductor substrate has a transistor formed on the first surface of the semiconductor substrate, and
wherein the transistor is coupled to the first conductive material.

12. The method of claim 11,
wherein the second trench is formed in the first insulating layer and the semiconductor substrate without penetrating the semiconductor substrate by the second etching, and
wherein the second conductive material is supplied with a power voltage.

13. A method comprising:
preparing an apparatus including a semiconductor substrate and a mask layer covering the semiconductor substrate, the apparatus having a first region and a second region;
forming a photoresist on the mask layer;
exposing the photoresist to a light via a photomask having a first aperture corresponding to the first region and a second aperture corresponding to the second region, the second aperture being lower in light transmissibility than the first aperture;
pattering the photoresist to have a first opening exposing the mask layer in the first region and a recess in the second region;
first etching the apparatus using the patterned photoresist to form a first trench in the first region, the first trench penetrating the mask layer to form a third opening in the mask layer and reaching the semiconductor substrate;
reducing a thickness of the patterned photoresist to form a second opening exposing the mask layer in the second region;
second etching the apparatus using the thickness reduced photoresist to form a fourth opening of the mask layer in the second region; and
third etching the apparatus using the mask layer having the third and fourth openings to increase a depth of the first trench in the first region and to form a second trench in the second region.

14. The method of claim 13, wherein the first trench penetrates the semiconductor substrate.

15. The method of claim 14, wherein the second trench does not penetrate the semiconductor substrate.

16. The method of claim 15,
wherein the apparatus further includes an insulating layer arranged between the semiconductor substrate and the mask layer, and
wherein the second trench does not penetrate the insulating layer.

17. An apparatus comprising:
a semiconductor substrate having a through hole penetrating the semiconductor substrate and a trench provided so as not to penetrate the semiconductor substrate;
a first conductive material embedded in the through hole; and
a second conductive material embedded in the trench,
wherein the first and second conductive materials comprise the same metal material.

18. The apparatus of claim 17, wherein the semiconductor substrate has a first surface on which the trench is opened, a second surface opposite to the first surface, and a transistor formed on the second surface.

19. The apparatus of claim 18, further comprising a conductor plug embedded in the semiconductor substrate,
wherein the conductor plug is coupled between the second conductive material and the transistor.

20. The apparatus of claim 17,
wherein the semiconductor substrate has a first surface on which the trench is opened and a transistor formed on the first surface, and
wherein the second conductive material is configured to be supplied with a power voltage to stabilize a potential of the power voltage.
